(19) United States
(12) Patent Application Publication
(10) Pub. No.: US 2021/0255376 A1
(43) Pub. Date: Aug. 19, 2021

(54) OPTICAL DEVICE AND A METHOD FOR BONDING

(71) Applicant: Unispectral Ltd., Ramat Gan (IL)

(72) Inventors: Eliahu Chaim ASHKENAZI, Jerusalem (IL); Ariel RAZ, Kfar Vradim (IL); Peleg LEVIN, Rishon Le-Zion (IL); Viacheslav KRYLOV, Holon (IL)

(21) Appl. No.: 17/056,356

(22) PCT Filed: May 16, 2019
(86) PCT No.: PCT/IB2019/054057

§ 371 Date: Nov. 17, 2020

Related U.S. Application Data
(60) Provisional application No. 62/672,739, filed on May 17, 2018.

(51) Int. Cl. G02B 5/28; B81B 3/00; G01J 3/26; G02B 26/00

(52) U.S. Cl. CPC G02B 5/284; B81B 3/0056; B81B 2201/042; G02B 26/001; G01J 3/26

(57) ABSTRACT

An optical device that may include an enclosure that comprises a first element, a second element; wherein the first element and the second element are at least partially transparent; a movable element that is configured to move within an internal space defined by the enclosure; and wherein the enclosure is sealed and is configured to maintain a pressure difference between a pressure level that exists within the internal space and an ambient pressure level.

### CROSS REFERENCE

This application claims priority from U.S. provisional patent Ser. No. 62/672,739 filing date May 17, 2018 which is incorporated herein in its entirety.

### BACKGROUND

There may be a need to provide optical devices that can maintain their integrity under different conditions.

### SUMMARY

There may be provided an optical device and a method for bonding as substantially illustrated in at least one of the specification, claims and drawings.

### BRIEF DESCRIPTION OF THE DRAWINGS

Non-limiting examples of embodiments disclosed herein are described below with reference to figures attached hereto that are listed following this paragraph. The drawings and descriptions are meant to illuminate and clarify embodiments disclosed herein and should not be considered limiting in any way. Like elements in different drawings may be indicated by like numerals.

FIG. 1A shows schematically in an isomeric view a tunable MEMS etalon device, according to an example of the presently disclosed subject matter;

FIG. 1B shows schematically the device of FIG. 1A with a cross section, according to an example of the presently disclosed subject matter;

FIG. 2A shows the device of FIG. 1B in an initial as-fabricated, non-stressed un-actuated state, according to an example of the presently disclosed subject matter;

FIG. 2B shows the device of FIG. 2A in an initial pre-stressed un-actuated state, according to an example of the presently disclosed subject matter;

FIG. 2C shows the device of FIG. 2B in an actuated state, according to an example of the presently disclosed subject matter;

FIG. 3 shows schematically a top view of the functional mechanical layer in the device of FIG. 1A or FIG. 1B, according to an example of the presently disclosed subject matter;

FIG. 4 shows schematically a top view of the cap in the device of FIG. 1A or FIG. 1B with multiple electrodes formed thereon, according to an example of the presently disclosed subject matter;

FIG. 5A shows schematically a tunable MEMS etalon device, in a cross-sectional view and in an initial as-fabricated, non-stressed un-actuated state, according to another example of the presently disclosed subject matter;

FIG. 5B shows the device of FIG. 5A in an initial pre-stressed un-actuated state, according to an example of the presently disclosed subject matter;

FIG. 5C shows the device of FIG. 5B in an actuated state, according to an example of the presently disclosed subject matter;

FIG. 6 shows a bottom view of the handle layer of the SOI wafer in the device of FIG. 5A or 5B, according to an example of the presently disclosed subject matter;

FIG. 7 shows an assembly comprising a device disclosed herein with integrated optics, according to an example of the presently disclosed subject matter;

FIG. 8 illustrates schematically in a block diagram a sequential imaging system configured according to an example of the presently disclosed subject matter;

FIG. 9 shows examples of various back mirrors, according to an example of the presently disclosed subject matter;

FIG. 10A shows schematically a tunable MEMS etalon device, in a cross-sectional view and in an initial as-fabricated, non-stressed un-actuated state, according to another example of the presently disclosed subject matter;

FIG. 10B shows the device of FIG. 10A in an initial pre-stressed un-actuated state, according to an example of the presently disclosed subject matter;

FIG. 10C shows the device of FIG. 10B in an actuated state, according to an example of the presently disclosed subject matter;

FIG. 11 shows in an isomeric view an example of a portion of an optical device;

FIG. 12 shows an example of a portion of an optical device;

FIG. 13 shows an example of a portion of an optical device;

FIG. 14 shows an example of a portion of an optical device;

FIG. 15 shows in an isomeric view an example of a portion of an optical device;

FIG. 16 shows an example of a portion of an optical device;

FIG. 17 shows an example of a portion of an optical device;

FIG. 18 shows an example of a portion of an optical device;

FIG. 19 shows an example of a portion of an optical device;

FIG. 20 shows an example of a portion of an optical device;

FIG. 21 shows an example of a portion of an optical device;

FIG. 22 shows an example of a portion of an optical device;

FIG. 23 shows an example of a portion of an optical device;

FIG. 24 shows an example of a portion of an optical device;

FIG. 25 shows an example of a portion of an optical device; and

FIG. 26 shows an example of a portion of an optical device.

### DETAILED DESCRIPTION

In the following discussing the term “glass” is used as a general non-limiting example of an at least partially transparent material. It is noted that the term glass should not be construed as limiting and other materials are also contemplated including any material or combination of materials with suitable transparency to light in a required wavelength range for the etalon and the image sensor to function in a desired way, for example plastic, silica, germanium, or silicon (silicon is transparent to wavelengths of roughly 1-8 μm).

An optical device, such as a Micro Electro Mechanical System (MEMS) based optical device, may include internal moving components. The dynamic motion of the internal moving components may be affected by the internal pressure of the optical device. Interaction of the moving components with gas molecules that are present inside the optical device often creates a significant damping effect which inhibits the motion of the internal moving components.

The agility of such an optical device is often characterized by a dimensionless parameter called the quality factor—which is often used in Physics to indicate the energy losses within a resonant element. Generally, the higher the quality factor is, the smaller are the damping effects and the faster is the dynamical response of the optical device.

To reduce unwanted damping effects, there is provided an optical unit that includes a sealed enclosure that may seal (and even hermetically seal) the optical device at a sufficiently high vacuum level. Low, medium, and high vacuum levels are generally defined as being in the ranges of 760-25, 25-1×10⁻³, 1×10⁻³−1×10⁻⁹ torr, respectively. Ultra and extremely high vacuum levels are pressure levels lower than 1×10⁻⁹ torr.

As an example, close to atmospheric pressure the squeeze film effect—the damping effect created by thin layers of gas, could result in very low-quality factors of the optical device, for example within the range of 1-100, and increased switching times, for example 100 milliseconds and above. However, the same optical device at medium and higher vacuum levels could exhibit increased quality factors which are by at least an order of magnitude higher—thus resulting in much shorter response times.

A pressure difference between an ambient pressure and the pressure within the enclosure may deform elements of the optical device. There may be provided an optical device that may include one or more deformation reduction elements that reduce (entirely or partly) deformations resulting from pressure differences between an internal space of the optical device and an exterior of the optical device.

There may be provided an optical device that may include one or more deformation reduction elements that reduce (entirely or partly) deformations resulting from pressure differences between an internal space of the optical device and an exterior of the optical device.

The optical device may include one or more deformation reduction elements for reducing deformations of a coated at least partially transparent element of the optical device. The deformation may result from various reasons—for example due to a residual stress of a coating or pressure differences, and the like. The coated at least partially transparent element may or may not be subjected to the pressure difference.

A deformation reduction element can be made of various materials. For example—the deformation reduction element can be made of LaTiO3, can be made of SiO2, can include LaTiO3, can include SiO2, can include both LaTiO3 and SiO2, can include alternating layers of LaTiO3 and SiO2, and the like.

Using a deformation reduction element of SiO2 may be beneficial as the refractive index of SiO2 is substantially similar (in the range of about 10-30%) to that of a transparent material (such as glass) included in the optical unit—in the range of the light's wavelengths used in the device. That what makes it relatively easy to use it in the device.

Other materials with different refractive indices may require an adaptation of the optical design of the optical unit.

In other examples, the deformation reduction element can be transparent, partially-transparent, or even opaque.

The one or more deformation reduction elements may be formed as one or more layers—but may be formed in any other shape.

The one or more deformation reduction elements may be integrated with one or more to other parts of the optical device and/or may be mechanically coupled to one or more other parts of the optical device in any manner.

The optical device may include (a) a first element that includes a first region that is at least partially transparent (transparent or semi-transparent), (b) a second element that includes a second region that is at least partially transparent, and (c) a movable element that includes a third region that is at least partially transparent and is positioned between the first and second regions. The optical device may or may not include one or more deformation reduction elements. The optical device may include a sealed enclosure that includes the first and second elements and one or more bonds. The sealed enclosure may be hermetically sealed.

Each one of the first, second or third elements may or may not include another region that is not partially transparent (for example is opaque).

The first and second elements may form an enclosure or may be a part of an enclosure that may be sealed and may define an internal space that may be maintained at a pressure level that is lower than a pressure level (ambient pressure level) of the exterior of the optical device. The movable element may move within the internal space.

The pressure level within the internal space may be a vacuum pressure level.

An optical path may pass through the first and second regions and the movable element.

The movable element can move and tilt in various directions. For simplicity of explanation it is assumed that the first and second elements are planar objects and that the movable element may move in relation to the first and second elements by performing a vertical movement. It should be noted that the movable element may move in other directions—such as within a horizontal plane, perform a rotating, perform any one of toll, pitch and/or yaw movements, and the like.

The movable element may move in relation to the first and/or second elements with or without touching the first and/or second elements. Non-limiting example of a minimal gap between the movable element and the first and/or second elements include 50 nm, 40 nm, 30 nm, 20 nm, or even 10 nm.

The optical device may include one or more stoppers that may define the minimal gap.

A ratio between (a) the minimal gap and (b) a largest dimension of the movable planar object (e.g. diameter, length, width, etc.) may be at least 1:10 and up to 1:100, 1:1000, 1:10000, 1:100000, 1:1000000 or even up 1:10000000.

In some implementations, there are no stopper elements and the movable element can come into contact with at least one of the first and second elements.

The movable element may be substantially parallel to at least one of the first and second elements.

Each one of the first and second elements may be exposed on one side to the pressure level of the internal space and may be exposed on another side to a pressure level of the exterior of the optical device.

For simplicity of explanation the pressure level of the internal space will be referred to as vacuum and the pressure level of the exterior of the optical device will be referred to as ambient pressure level.

Without the one or more deformation reduction elements—the difference between the ambient pressure level and the vacuum may deform the first and/or second elements. The one or more deformation reduction elements are configured (constructed and arranged) to at least partially reduce this deformation.

It should be noted that a deformation of the first element and a deformation of the second element may affect the performance of the optical device in the same manner or in different manners. Accordingly—deformation of the first and second elements may be tolerated in the same manner or in different manners. For example—the deformation of the second element may be more problematic than the deformation of the first element.

Only one of the first and second elements may be provided with a deformation reduction element or both the first and second elements may be provided with deformation reduction elements.

The number of deformation reduction elements related to (integrated with, mechanically coupled to, deposited on) the first element may differ from (or may be equal to) the number of deformation reduction elements related to the second element.

The optical device may include multiple deformation reduction elements.—At least two of the multiple deformation reduction elements may be identical to each other. Two or more of the of the multiple deformation reduction elements may differ from each other.

A deformation reduction element may be more rigid than the first region, may be more rigid than the first element, may be more rigid than the second region and/or may be more rigid than the second element.

A deformation reduction element may be less rigid than the first region, may be less rigid than the first element, may be less rigid than the second region and/or may be less rigid than the second element.

A deformation reduction element may have the same rigidness as the first region, may have the same rigidness as the first element, may have the same rigidness as the second region and/or may have the same rigidness as the second element.

There may be various spatial relationships between the first element, the second element and any one of the deformation reduction elements.

For example—a deformation reduction element may cover an entirety of the first element, may only cover a part of the first element, may cover only the first region, may cover more than the first region but less than the first element, may cover an entirety of the second element, may only cover a part of the second element, may cover only the second region, may cover more than the second region but less than the second element.

A projection of a deformation reduction element on the first region have a same shape as the first region or may have a different shape than the first region.

A projection of a deformation reduction element on the second region have a same shape as the second region or may have a different shape than the second region.

A deformation reduction element may be integrated with the first element, may be mechanically coupled to the first element, may coat the first element, may be a part of the first element, may be integrated with the first region, may be mechanically coupled to the first region, may coat the first region, may be a part of the first region, may be integrated with the second element, may be mechanically coupled to the second element, may coat the second element, may be a part of the second element, may be integrated with the second region, may be mechanically coupled to the second region, may coat the second region, may be a part of the second region, and the like.

Any deformation reduction element may be opaque, or at least partially transparent.

A first group of one or more deformation reduction elements may be associated (mechanically coupled to, integrated with, and the like) with the first element.

Without the first group the first element may be deformed (due to the pressure difference) at a certain manner. The first group may counter (fully or partially) this deformation.

For example—if the first element (at the absence of the first group) tends to bend inwards due to the pressure differences—the first group may tend to bend outwards—and/or to counter (fully or partially) the inward bending For example- if the first element tends to bend outwards due to the pressure differences—the first group may tend to bend inwards—and to counter (fully or partially) the outward bending.

A deformation reduction element may merely stiffen the element it attached to.

A second group of one or more deformation reduction elements may be associated (mechanically coupled to, integrated with, and the like) with the second element.

Without the second group the second element may be deformed (due to the pressure difference) at a certain manner. The second group may counter this deformation.

For example—if the second element tends to bend inwards due to the pressure differences—the second group may tend to bend outwards—and/or to counter (fully or partially) the inward bending. For example—if the second element tends to bend outwards due to the pressure differences—the second group may tend to bend inwards—and to counter (fully or partially) the outward bending.

The optical device may be a tunable filter, a Fabry-Perot tunable filter, an interferometer, a Fabry-Perot interferometer, a tunable MEMS etalon device, and the like. The terms Fabry-Perot tunable filter, interferometer, Fabry-Perot interferometer, and a tunable MEMS etalon device are used in an interchangeable manner.

The second element may act as one or the mirrors (for example—a back mirror) of the Fabry-Perot tunable filter—thus reducing the overall size of the Fabry-Perot tunable filter and improving the accuracy of the Fabry-Perot tunable filter—as the Fabry-Perot tunable filter may include fewer mechanical elements.

The movable element may move due to electrostatic actuation, by piezoelectric actuation or by any other actuation method. The movable element may include springs such as MEMS fabricated springs.

The actuation of the movable element could either be periodic or non-periodic, where within each period or non-period its movement could resemble a harmonic response, a step response, or any other simple or complex forms of a dynamical response.

The internal space may be sealed by an enclosure that includes the first and second elements. The enclosure can be hermetically sealed. The pressure level within the internal space may be set during the manufacturing process of the optical device.

Sealing may be achieved by various types of sealants, bonds, etc. A eutectic bond is a non-limiting example of a bond—other bonds may be used.

There may be provided an optical unit in which one or more eutectic bonds are formed between bonded elements. A eutectic bond may be formed between bonded elements of the same materials or between bonded elements of different materials. For example—a eutectic bond can be formed between (a) glass and glass and/or (b) between glass and silicon.

The optical device may be a tunable filter, a Fabry-Perot tunable filter, an interferometer, a Fabry-Perot interferometer, a tunable Micro Electro Mechanical Systems (MEMS) etalon device, any device which can affect any of the properties of light such as direction, spectral content, polarization mode, either in discrete modes or continuously, and the like.

One of the requirements of a eutectic bond is to have a high degree of parallelism between the bonded elements. This requirement may be important when the two bonded elements are made of glass (and the level/degree of light property tunability relies on gap uniformity between two mirrors)—but this is not necessarily so.

A recess (for example a tunnel) may be formed in at least one of the bonded elements. Before the bonded elements are pressed against each other—the recess may be only partially filled by the eutectic bonding material that will eventually bond the bonded elements. The space in which the eutectic bonding material is located may be referred to as the main space. When the bonded elements are pressed against each other the eutectic bonding material is flattened and is forced to move towards one or more parts of the recess that were initially empty. These parts are also referred to as excess spaces.

This allows the entire eutectic bonding material to remain within the recess (or have another predefined relationship with the recess) rather than overflow due to the applied pressure—and may thus increase the parallelism between the bonded elements.

The eutectic bond may be replaced by (or may be provided in addition to) another bond such as but not limited to glass frit bond, laser glass frit, etc. A recess may be formed in a bonded element for receiving the eutectic bonding material—especially when the bonded elements are required to contact each other after the bonding.

It should be noted that the eutectic bonding material may be partially positioned within a recess formed in one of the bonded elements and may also partially extend from the recess that is formed in that bonded element.

The eutectic bonding material may be positioned outside the bonded elements to form an external eutectic bond. One or more spacers may also be positioned between the bonded elements. One or more spacers may be initially connected to one of the bonded elements and one or more other spacers may be initially connected to another one of the bonded elements. All the spacers may be connected to a single bonded element.

The spacers may be positioned on both sides of the external eutectic bond. The external eutectic bond extends outside any of the bonded elements. For example—these spacers may include internal spacers and external spacers. If the external eutectic bond surrounds an area of a bonded element—then the internal spacers may fall on that area while the external spacers may fall outside that area.

The internal spacers and the external spacers may be arranged in groups—for example in pairs—wherein each pair may include an internal spacer that faces an external spacer. A segments of the external eutectic bond is located between the internal and external spacers of the pair.

The disposition of the internal and external spacers on two sides of the external eutectic bond may substantially equalize a torque that may result when only one-side spacers are disposed. The torque can result from the shrinkage of the eutectic bond between its as applied and final states.

The spacers can be configured to maintain, in a controllable way, a minimal desired gap between the two bonded elements.

The spacers may be shaped as pillars that are spaced apart from each other in equal intervals. The spacer may have other shapes and may be spaced apart from each other by uneven intervals. Using spaced apart (segregated) spacers can reduce the stress and bending to moments applied on the cap by the deposition/formation/addition of spacers.

One of the bonded elements may be made of silicon and the other bonded element may be made of glass.

The eutectic bonding material may be electrically conductive and may electrically couple one bonded element to another, may provide a conductive path between conductors of the bonded elements, or may provide a conductive path between one bonded element and a non-conductive (or semi-conductive) element of another bonded element. An example of a conductor may include a through via or a through conductor that passes through a substantially semi-conductive or non-conductive bonded element.

For example—a transparent or semi-transparent element (e.g. a glass element) may have a through-hole that is filled with a conductive material (e.g. Tungsten) for conducting electric current from both sides of the filled through-hole. At least a portion of the eutectic bonding material that participates in the eutectic bond may be in contact with a conductive material to conduct electric current to an element that may function as ground or have other functionalities.

The conductive path may or may not be grounded.

One of the bonded elements may include an at least partially transparent region, may be a deformation reduction element, may be mechanically coupled to a deformation reduction element, and the like.

There is also provided a method for bonding an anchor that surrounds a movable element to a second element of a tunable filter. The method may include pressing the anchor to a second element, the second element is formed with a recess for containing the eutectic bonding material for bonding the anchor and the second element, wherein the recess may initially be only partially filled by the eutectic bonding material. Wherein the pressing of the anchor to the second element causes the eutectic bonding material to be flattened and to be forced to move towards one or more parts of the recess that were initially empty.

There is also provided a method for bonding bonded elements of a tunable filter. The method may include pressing one bonded element to another bonded element, wherein one of the bonded elements is formed with a recess for containing the eutectic bonding material for bonding the bonded elements. Wherein the recess may initially be only partially filled by the eutectic bonding material. Wherein the pressing of the anchor to the second element causes the eutectic bonding material to be flattened and to be forced to move towards one or more parts of the recess that were initially empty

There is also provided a method for bonding bonded elements of a tunable filter. The method may include pressing one bonded element to another bonded element while maintaining, by spacers that surround a eutectic bond, a gap between the bonded elements. It should be noted that the eutectic bonding material may be located within a recess that has sidewalls on both sides of the eutectic bonding material—which also operate as spacers that are located at both sides of the eutectic bonding material.

It should be noted that an optical device may include multiple bonds formed between multiple sets of bonded elements. The multiple bonds may be of the same type (for example—may be eutectic bonds). Alternatively—at least two bonds of the multiple bonds may be of different types (for example—one bond is a eutectic bond and another bond is an anodic bond).

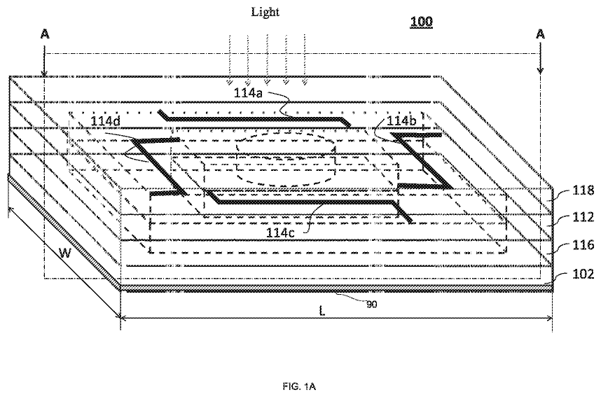

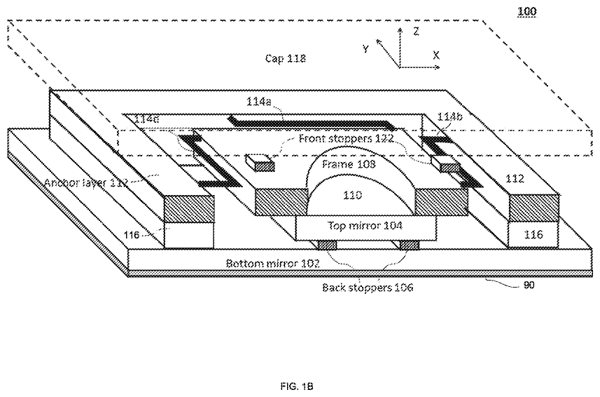

In FIGS. 1A, 1B, 2A, 2A, 2B, 2C, 3, 4, 5A, 5B, 5C, 6, 7, 8, 9, 10A, 10B, 10C, and 11-15 the optical device is a tunable MEMS etalon 100, the first element is cap 118, the second element is back mirror 102 and the movable element includes top mirror 104.

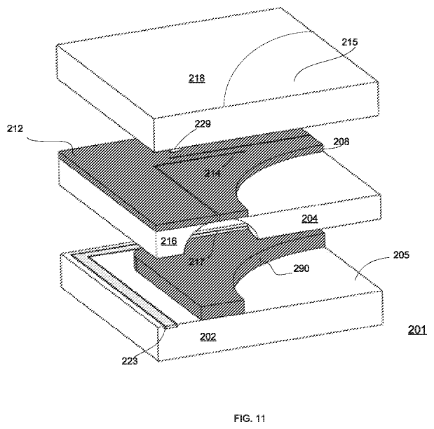

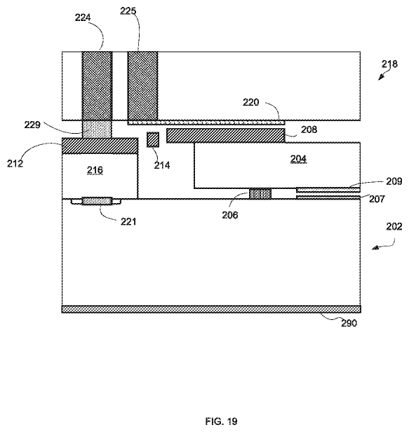

FIGS. 1A, 1B, 2A, 2B, 2C, 5A, 5B, 5C, 7, 10A, 10B, 10C and 11-15, and 17-26 illustrate examples of tunable MEMS etalon devices that include a deformation reduction element such as deformation reduction layer 90 or 290 in FIG. 11-14. Deformation reduction layer 90 may be a part of a bottom mirror 102, may be deposited on the bottom mirror or may be otherwise mechanically coupled to the bottom mirror 102. FIGS. 19-26 are cross sectional views of a left half of the optical device.

Although these figures illustrate deformation reduction layer 90 as being located at the external part of the bottom mirror 102- it should be noted that the deformation reduction layer 90 may be positioned elsewhere.

The optical device may have a pre-stressed state. Alternatively—the optical device may not have any pre-stressed state.

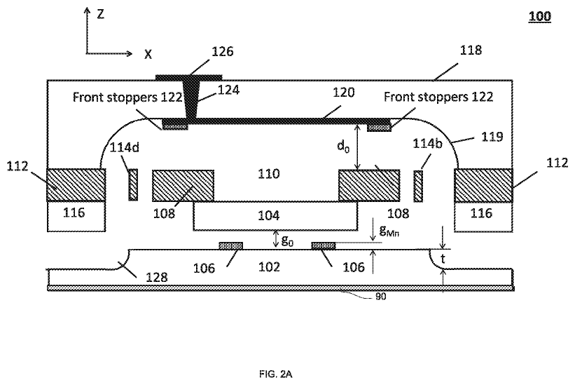

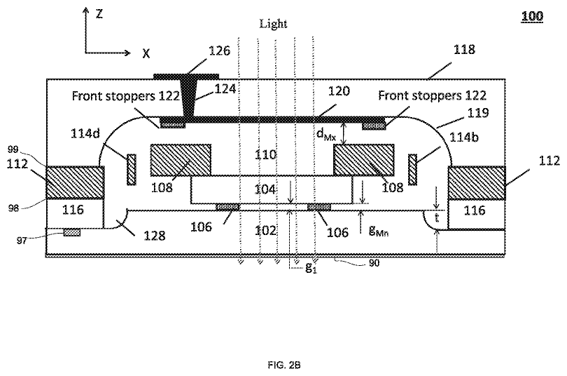

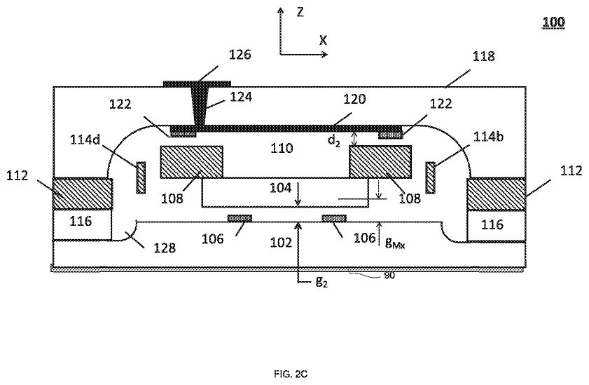

It should be noted that each of the tunable MEMS etalon devices of FIGS. 1A, 1B, 2A, 2A, 2B, 2C, 3, 4, 5A, 5B, 5C, 6, 7, 8, 9, 10A, 10B, 10C, may include one or more bonds or one or more types (including, for example, an eutectic bond, an anodic bond and the like), may include recesses for receiving eutectic bonding material, may include spacers for supporting any bond from both sides of the bond, and the like. For simplicity of explanation only FIG. 2B (out of FIGS. 1A, 1B, 2A, 2A, 2B, 2C, 3, 4, 5A, 5B, 5C, 6, 7, 8, 9, 10A, 10B, 10C) illustrates recess 97 for receiving eutectic bonding material, an anodic bond 98 between spacer 116 and anchor 112 and yet another bond 98 between cap 118 and anchor 112. The bonds may assist in sealing the enclosure.

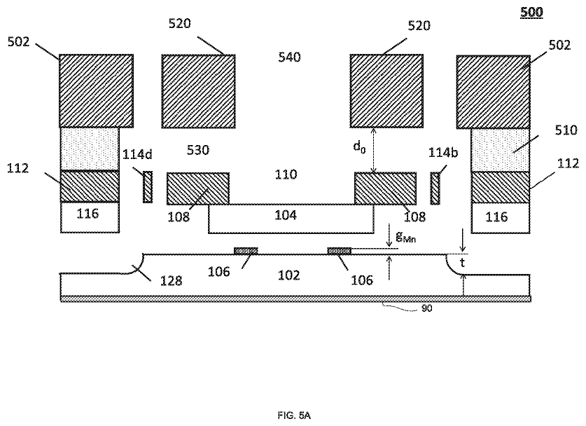

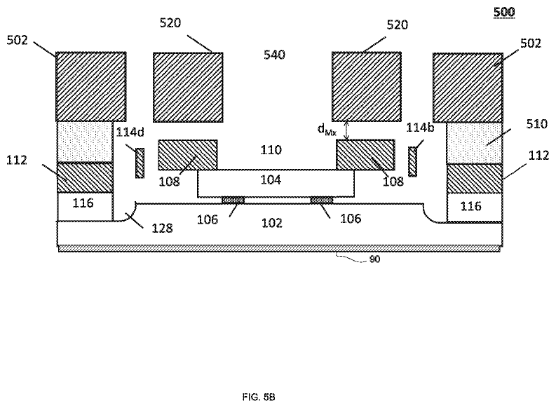

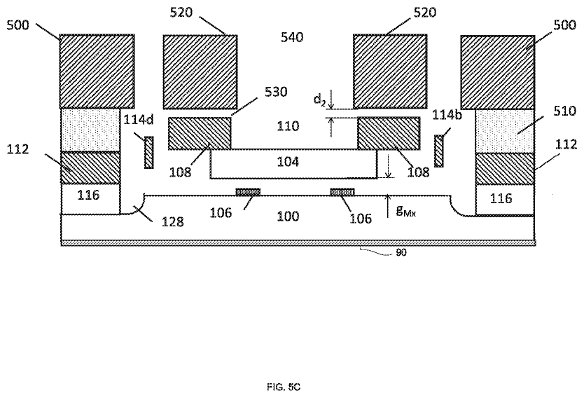

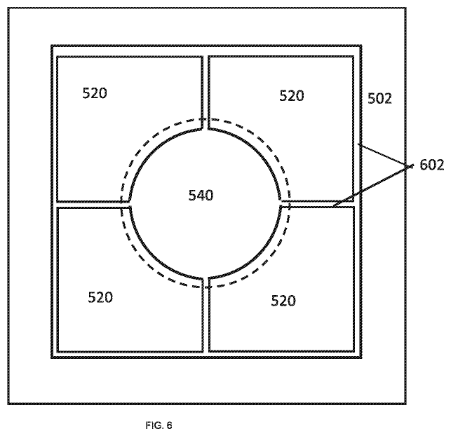

FIGS. 5A, 5B, 5C, and 6 illustrate optical devices that are not sealed. Each one of these optical devices may be sealed using, for example, one or more bonds, and/or other structural elements, as illustrated in relation to one or more other figures of the specification.

FIG. 1A shows schematically in an isomeric view a first example of a tunable MEMS etalon device disclosed herein and numbered 100. FIG. 1B shows an isomeric cross section of device 100 along a plane marked A-A. Device 100 is shown in conjunction with a XYZ coordinate system, which also holds for all following drawings. FIGS. 2A, 2B and 2C show cross sections of device 100 in plane A-A in three configurations (states): an as-fabricated (non-stressed) un-actuated state (FIG. 2A), a pre-stressed un-actuated state (FIG. 2B), and an actuated state (FIG. 2C). Device 100 comprises two substantially flat and parallel mirrors/reflective-surfaces, a bottom (or “back”) mirror 102 and a top (or “aperture”) mirror 104 separated by a “back” gap. As used herein, the terms “front” and “back” reflect the orientation of the device toward light rays.

As shown, the front (top) mirror is the first mirror in the path of light rays entering the etalon. In one example, the minors are formed in flat plates or wafers made of transparent or semi- transparent material to light in a desired wavelength range transmitted by the tunable etalon filter (e.g. glass). As used herein, the term “plate”, “wafer” or “layer” refers to a substantially two-dimensional structure with a thickness defined by two parallel planes and having a width and a length substantially larger that the thickness. “Layer” may also refer to a much thinner structure (down to nanometers-thick, as opposed to a typical thickness of micrometers for the other layers).

In an embodiment, back mirror 102 is formed in a glass layer that also serves as a substrate of the device. In other embodiments, back mirror 102 may be formed in a “hybrid” plate or hybrid material such that a central section (“aperture”) through which the light rays pass is transparent to the wavelength of the light (made e.g. of a glass), while plate sections surrounding the aperture are made of a different material, for example silicon. The hybrid aspect may increase the stiffness and strength of the mirror.

In the as-fabricated state, FIG. 2A, the back gap between the front and back mirrors has a size marked by g₀. In the un-actuated state, FIG. 2B, the back gap has a size marked by g₁. In an actuated state, FIG. 2C, the back gap has a size marked by g₂. The minors are movable with respect to each other so that back gap can be tuned between certain minimal (g_{Mn}) and maximal (g_{Mx}) gap sizes. The movement is in the Z direction in the particular coordinate system shown. Specifically, according to certain examples disclosed herein, back mirror 102 (facing sensor side relative to front mirror) is fixed and front mirror 104 (facing object side relative to back mirror) is movable. The gap size is minimal in the pre-stressed un-actuated state, so g₁=g_{Mn}. The maximal back gap size g_{Mx} corresponds to a “maximal” actuated state. There are of course many actuated states (and even a continuous range of states) in which the back gap has a value g₂ between g_{Mn} and g_{Mx}.

Device 100 further comprises a first stopper structure (also referred to as “back stoppers”) 106 positioned between minors 102 and 104 in a way such as not to block light rays designed to reach an image sensor. Back stoppers 106 may be formed on either mirror. In the initial as-fabricated un-actuated state, FIG. 2A, the two mirrors are located in a close proximity to each other, the minimal gap distance g_{Mn} being defined by back stoppers 106 which function as displacement limiters. An additional function of stoppers 106 is to prevent undesirable displacement of the front mirror due to external shock and vibration. Back stoppers 106 are designed to prevent contact between the mirrors and ensure that g_{Mn} is never zero. They may be located within an optical aperture area if their size is small and they do not obscure significantly the optical signal. The location of the back stoppers within an optical aperture area may be optimized in such a way that the displacement of movable front mirror 104 is minimal. In some examples, back stoppers 106 are made of a metal such as patterned Cr-Au layer, Ti-Au layer or Ti-Pt layer. The degrees of reflectivity/transparency of the top and back minors are selected in accordance with the desired spectral transmission properties of the etalon. According to some examples, each mirror is at least semi-reflective to some degree.

Device 100 further comprises a mounting frame structure (or simply “frame”) 108 with an opening (“aperture”) 110. Frame 108 is made of a transparent or semi-transparent material (for example single crystal silicon) and is fixedly attached (e.g. by bonding) to front mirror 104. That is, mirror 104 is “mounted” on frame 108 and therefore moves together with frame 108. Opening 110 allows light rays to enter the etalon through the front mirror. Therefore, the front mirror is also referred to sometimes as “aperture mirror”.

In some examples, back mirror 102 and optionally front mirror 104 include a Titanium Oxide (TiO₂) layer deposited on a glass layer/substrate. In certain examples, a device disclosed herein may comprise one or more electrodes (not shown) formed on back mirror 102 on the surface facing frame 108, to enable actuation of the frame structure (and thereby cause movement of the front mirror) toward the back mirror. Alternative actuation mechanisms may be applied, e.g. piezoelectric actuation, Kelvin force, etc. The movement of the front mirror towards or away from the back mirror tunes the spectral transmission band profile of the etalon.

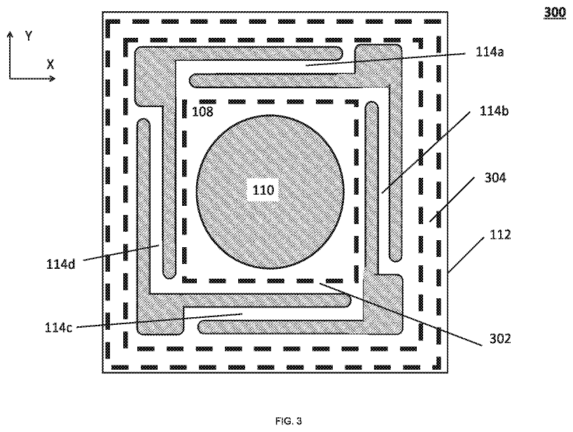

Device 100 further comprises an anchor structure (or simply “anchor”) 112, made of a transparent or semi-transparent material (for example single crystal silicon). Anchor 112 and frame 108 are attached to each other by a flexure/suspension structure. The suspension structure may be for example a region of anchor structure 112 patterned in the form of a bending or torsional spring, a combination of such springs, or as a thin doughnut-shaped membrane adapted to carry the front mirror. In device 100, the suspension structure includes a plurality of suspension springs/flexures. According to some examples, in device 100, the plurality of suspension springs/flexures includes four springs, 114a, 114b, 114C and 114d, made of transparent or semi-transparent material (for example single crystal silicon. Together, frame 108, anchor 112 and springs 114 form a “functional mechanical layer” 300, shown in a top view in FIG. 3. In the following discussing the term “silicon” is used as a general non-limiting example. It is noted that the term silicon should not be construed as limiting and other materials are also contemplated including any material or combination of materials with suitable flexibility and durability required for the flexure structure to function in a desired way, for example plastic or glass.

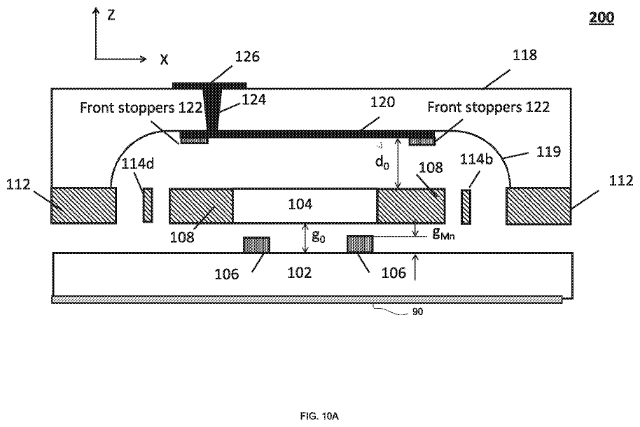

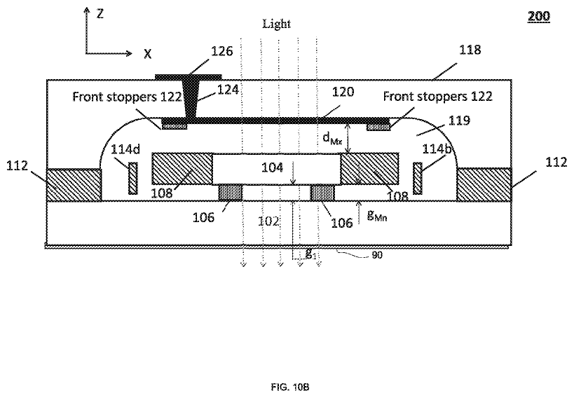

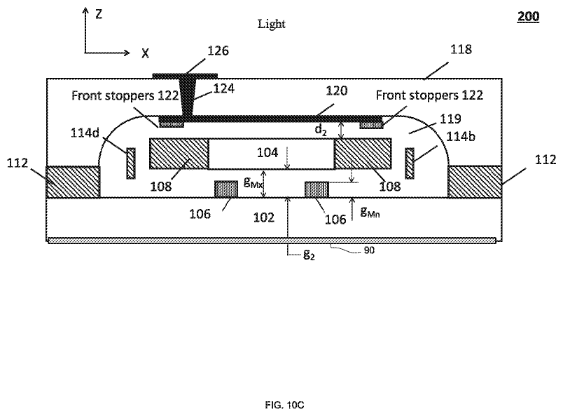

FIGS. 2A-2C show that a surface of front mirror 104 facing incoming light is attached to frame 108. A different configuration of front mirror 104 and frame 108 is described below with reference to FIG. 10. It also shows that a flexure structure, comprising four springs 114a, 114b, 114C and 114d (see FIG. 3), is attached to anchor 112 and to frame structure 108 but not attached to the front mirror.

In some examples, frame 108 is spaced apart from back mirror 102 by a spacer structure (or simply “spacers”) 116. According to some examples, spacers 116 can be formed of a glass material. Spacers 116 are used to separate the frame and springs from the plate in which mirror 102 is formed. While in principle silicon anchors 112 could be attached to the bottom plate directly without spacers 116, this requires very large deformation of the springs. For the adopted geometry, this deformation is beyond the strength limit of the spring material, which requires the presence of spacer layer 116. For technological reasons, in some examples, both movable front mirror 104 and spacers 116 are fabricated from the same glass plate (wafer). This simplifies fabrication, since the glass and silicon wafers are bonded at wafer level. For this reason, device 100 is referred to herein as a glass-silicon-glass (GSG) device.

Device 100 further comprises a cap plate (or simply “cap”) 118 accommodating at least part of an actuation mechanism configured for controlling gap size between the front mirror and the back mirror. As shown cap 118 is located at object side relative to front mirror 104 at the direction of incoming light. In the example of electrostatic actuation, cap 118 accommodates electrodes 120 formed on or attached thereto (see FIGS. 2A to 2C). Electrodes 120 can be positioned for example at a bottom side (facing the mirrors) of cap 118. Electrodes 120 are in permanent electrical contact through one or more through-glass vias 124 with one or more bonding pads 126 positioned on the opposite (top) side of cap 118. Electrodes 120 are used for actuation of frame 108 (thereby causing movement of front mirror 104). The cap comprises a first recess (cavity) 119 to provide a “front” (also referred to as “electrostatic”) gap d between frame 108 and electrodes 120. In the as-fabricated configuration (before the bonding of the device to the back mirror), FIG. 2A, gap d has a size d₀. After bonding, in the pre-stressed un-actuated state shown in FIG. 2B, gap d has a maximal size d_{Mx}. In any actuated state (as in FIG. 2C), gap d has a size d₂. Device 100 further comprises front stoppers 122 that separate between frame 108 and cap 118. In some examples, front stoppers 122 isolate electrically (prevent electrical shorts between) frame 108 from cap electrodes 120. In some examples, front stoppers 122 defines a maximal gap between front mirror 104 and back mirror 102.

In one example, the cap is made of a glass material. In other examples, cap 118 may be made of a “hybrid” plate or hybrid material such that a central section (“aperture”) through which the light rays pass is transparent to the wavelength of the light (made e.g. of a glass), while plate sections surrounding the aperture are made of a different material, for example silicon. The hybrid aspect may increase the stiffness and strength of the cap.

In certain examples, particularly where imaging applications are concerned, the length L and width W (FIG. 1A) of mirrors 102 and 104 should on one hand be large enough (e.g. on the order of several hundred micrometers (μm) to several millimeters (mm)) to allow light passage to a relatively wide multi-pixel image sensor. On the other hand, the minimal gap g_{Mn} should be small enough (e.g. a few tens of nanometers (nm)) to allow desired spectral transmission properties of the etalon. This results in a large aspect ratio of the optical cavity between the mirrors (e.g. between the lateral dimensions W and L and the minimal gap distance g_{Mn}), which in turn requires that accurate angular alignment is maintained between the mirrors to reduce or prevent spatial distortion of the chromatic spatial transmission band of the etalon along the width/lateral spatial directions thereof In some examples, g_{Mn} may have a value of down to 20 nanometers (nm), while g_{Mx} may have a value of up to 2 μm. According to one example, the value of g_{Mx} may be between 300 to 400 nm. Specific values depend on the required optical wavelength and are dictated by a specific application. Thus, g_{Mx} may be greater than g_{Mn} by one to two orders of magnitude. In certain examples, L and W may each be about 2 millimeter (mm) and springs 114 may be each about 50 μm thick, about 30 μm wide and about 1.4 mm long. In certain examples, the thicknesses of the glass layers of the cap 118, the back mirror 102 and the front mirror 104 may be about 200 μm. In some examples, L=W.

It should be understood that all dimensions are given by way of example only and should not be considered as limiting in any way.

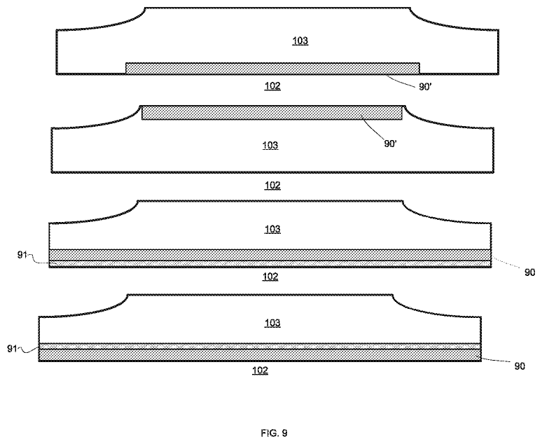

FIGS. 2A-2C provide additional information on the structure of device 100 as well as on the function of some of its elements. As mentioned, FIG. 2A shows device 100 in an initial as-fabricated and un-actuated, non-stressed state. As-fabricated, front mirror 104 does not touch back stoppers 106. FIG. 2B shows the device of FIG. 2A in an initial pre-stressed un-actuated state, with front mirror 104 physically touching back stoppers 106. The physical contact is induced by stress applied on the frame through the springs when spacer layer 116 is forced into contact with the glass wafer substrate (which includes back mirror 102) for eutectic bonding of spacers 116 to the glass plate of back mirror 102, see FIG. 9(c) below. Thus, the configuration shown in FIG. 2B (as well as in FIG. 5B) is said to be “pre-stressed”. FIG. 2C shows the device in an actuated state, with front mirror 104 in an intermediate position between back stoppers 106 and front stoppers 122, moved away from back mirror 102.

In some examples, back mirror 102 includes a second recess 128 with a depth t designed to provide pre-stress of the springs after assembly/bonding. According to some examples, recess depth t is chosen on one hand such that the contact force arising due to the deformation of the springs and the attachment of front movable mirror 104 to back stoppers 106 is high enough to preserve the contact in the case of shocks and vibrations during the normal handling of the device. On the other hand, in some examples, the combined value of recess depth t plus the maximal required travel distance (maximal back gap size) g_{Mx} is smaller than one third of an as-fabricated (“electrostatic”) gap size d₀ of a gap between electrodes 120 and frame 108 (FIG. 2A), to provide stable controllable electrostatic operation of the frame by the electrodes located on the cap. In certain examples, the as-fabricated electrostatic gap d₀ may have a value of about 3-4 μm and t may have a value of about 0.5-1 μm. The requirement for stable operation is t+g_{Mx}<d₀/3, since the stable travel distance of a capacitive actuator is ⅓ of the as-fabricated electrostatic gap, i.e. is d₀/3.

Note that in certain examples, an un-actuated state may include a configuration in which movable mirror 104 is suspended and does not touch either back stoppers 106 or front stoppers 122.

In the actuated state, shown in FIG. 2C, the mounting ring and the front mirror are displaced away from the back mirror. This is achieved by applying a voltage V between the one or more regions/electrodes 120 of the actuation substrate serving as an actuating electrode and the one or more regions frame 108.

According to some examples, device 100 is fully transparent. It includes a transparent back mirror (102), a transparent front mirror (104) and a transparent cap (118) as well as transparent functional mechanical layer 300. One advantage of the full transparency is that the device can be observed optically from two sides. Another advantage is that this architecture may be useful for many other optical devices incorporating movable mechanical/optical elements, such as mirrors, diffractive gratings or lenses. In some examples, device 100 is configured as a full glass structure, where the functional mechanical layer includes a glass substrate that is pattered to accommodate/define the suspension structure carrying the top mirror, the suspension structure including a plurality of glass springs/flexures.

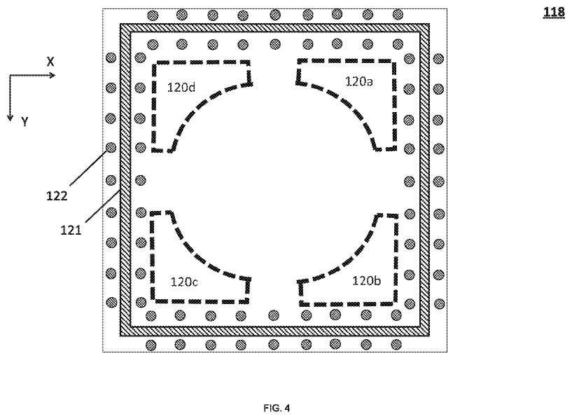

FIG. 3 shows schematically a top view of functional mechanical layer 300. The figure also shows an external contour 302 of front mirror 104, aperture 110, anchor structure 112, springs 114a-d (flexure structure) and a contour 304 enclosing a eutectic bond frame 121 and cap spacers 122 as further described in more detail with reference to FIG. 4 below.

FIG. 4 shows schematically a top view of cap 118 with a plurality of electrodes 120, marked here 120a, 120b, 120c and 120d. The number and shape of electrodes 120 shown are shown by way of example only and should not be construed as limiting. According to some examples, three electrodes 120 are required to control both the displacement of the frame in the Z direction and the tilting of the frame about X and Y axes. Multiple electrode regions, e.g. as shown in FIG. 4, may be fabricated on cap 118 such that front mirror 104 can be actuated with an up-down degree of freedom (DOF) along the Z direction and can also be tilted (e.g. with respect to two axes X and Y) to provide additional angular DOF(s). This allows adjustment of angular alignment between front mirror 104 and back mirror 102. According to some examples, cap 118 may include a deposited eutectic bonding material 121. Furthermore, spacers 122 may be used to precisely control the electrostatic gap between the cap electrodes 120 and the actuator frame 108 serving as the second electrode. According to the presently disclosed subject matter, the eutectic bonding material 121 can be made to assume the shape of a frame. In such case, spacers 122 can be placed on both sides of the frame (inner and outer) and thereby minimize bending moments acting on the cap as a result of the eutectic bonding shrinkage during the bonding process.

Following is an example of a method of use of device 100. Device 100 is actuated to bring the etalon from the initial pre-stressed un-actuated state (FIG. 2B) to an actuated state (e.g. as in FIG. 2C). The actuation moves frame 108 and front mirror 104 away from back mirror 102, increasing the back gap between the mirrors. An advantageously stable control of the back gap is enabled by the innovative design with an initial as-fabricated (and non-stressed) state. More specifically, this design includes an initial maximal as-fabricated (and non-stressed) front gap size d₀ (FIG. 2A), which is about three times larger than the combined recess depth t and the maximal required travel (back gap) size g_{Mx}. This is because the stable range of the parallel capacitor electrostatic actuator is one third of the initial distance between the electrodes.

According to one example, device 100 may be used as a pre-configured filter for specific applications. For example, the device may be pre-configured to assume two different states, where the gap between the mirrors in each one of the two states (as set by the stoppers) is according to the desired wavelength. For example, one state provides a filter that allows a first wavelength range to pass through the etalon, while the other state allows a second wavelength range to pass through the etalon. The design for such a “binary mode” filter is related to a simple and accurate displacement of the mirrors between the two states and allows simplified manufacturing.

According to one example, one state is the initial un-actuated etalon state g₁ (where the gap size between the mirrors is defined by stoppers 106) selected to allow a first wavelength range to pass through the etalon and the other state is one actuated state in which the gap has an actuated gap size g₂, greater than the pre-stressed un-actuated gap size and resulting in electrical gap d₂ which is equal to the height of front stoppers 122, selected to allow a second wavelength range to pass through the etalon. In the second state frame 108 is in contact with front stoppers 112.

FIGS. 5A-5C show schematically in cross-sectional views a second example of a tunable MEMS etalon device disclosed herein and numbered 500. FIG. 5A shows device 500 in an as-fabricated (non-stressed) configuration, before the bonding of spacers 116 to the back mirror 102. FIG. 5B shows device 500 in an initial pre-stressed un-actuated state, while FIG. 5C shows device 500 in an actuated state. Device 500 uses a SOI wafer and SOI fabrication technology and is therefore referred to herein a “SOI device”, in contrast with GSG device 100. Device 500 has a similar structure to that of device 100 and includes many of its elements (which are therefore numbered the same). Since both SOI wafers and technology are known, the following uses SOI terminology known in the art.

In FIG. 5A, front mirror 104 is not in physical contact with the back stoppers 106 on back mirror 102, while in FIG. 5B, the pre-stress brings front mirror 104 and back stoppers 106 into physical contact. In FIG. 5C, front mirror 104 has moved away from back mirror 102 and is in an intermediate position between the back stoppers 106 and electrodes 520, which in the SOI device are made of a handle layer 502 of the SOI wafer. The SOI wafer is used such that the handle layer serves as a substrate as well as for fabrication of electrodes 520. Frame 108 includes regions that serve as the opposite electrode. An anchor structure (layer) 112 in the device Si layer of the SOI wafer is connected to frame 108 through springs 114a-d. Anchor structure 112 is attached to handle layer 502 through a BOX layer 510. A gap between the Si device and handle layers is indicated by 530. Gap 530 is created by etching the BOX layer 510 under the frame and under the springs. An opening 540 is formed in handle layer 502, exposing front mirror 104 and back mirror 102 to light rays in the −Z direction.

In the as-fabricated state, before the bonding of spacers 116 to the glass plate comprising back mirror 102, gap 530 between the frame and the handle layer has a size d₀ and is equal to the thickness of the BOX layer, FIG. 5A. After the bonding, gap 530 has a size d_{Mx} equal to the thickness of BOX layer 510 minus the depth t of recess 128 and minus the height of back stoppers 106. Thus, d_{Mx} is smaller than d₀ due to the pre-stress, since when front mirror 104 contacts back stoppers 106 the springs are deformed and the size of released gap 530 decreases. Upon actuation, FIG. 5C, frame 108 pulls front mirror 104 away from back mirror 102, further decreasing the size of gap 530 to d₂ and increasing the size of the back gap (at most, up to a maximal size g_{Mx}).

FIG. 6 shows a schematic illustration of a bottom view of the handle layer of the SOI wafer. The figure shows an insulating trench 602 between electrodes 520. In certain examples, one or more regions/electrodes of the handle layer 520 may include two or more regions that are substantially electrically insulated from one another. Accordingly, application of different electric potentials between these two or more regions of handle layer 520 and of frame 108 allows adjusting parallelism between the front mirror and the back mirror. For instance, the two or more regions of the handle layer may include at least three regions, arranged such that parallelism between the front and back mirrors can be adjusted two-dimensionally with respect to two axes.

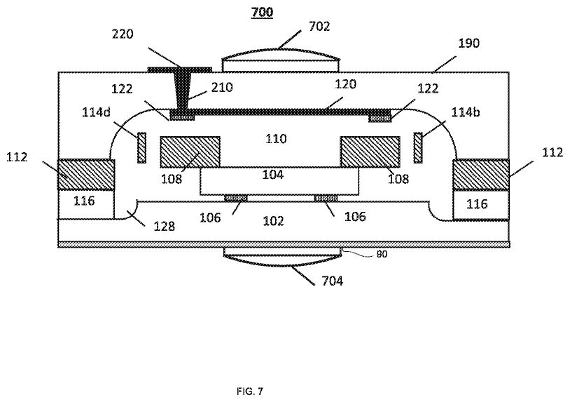

FIG. 7 shows a schematic illustration of an assembly comprising a device 700 with a lens 702 formed in, on, or attached to the cap, and a lens 704 formed in, on, or attached to the back mirror. This allows integration of optics with the etalon to provide an “optics” tunable etalon device. Also, in case there is an under-pressure inside the cavity between the two glasses, the addition of such lenses improves the stiffness and decreases deformation of the back mirror and of the cap. Other elements are as marked in device 100.

Tunable etalons disclosed herein in devices 100 and 500 may be used for imaging applications. For example, these devices may be designed and used as a wide dynamic filter tunable over a wide spectral band (e.g. extending from infra-red [IR] or near-IR (NIR) wavelengths in the long wavelength side of the spectrum, through the visible (VIS) range down to the violet and/or ultra-violet (UV) wavelengths at the short wavelength side of the spectrum. Additionally or alternatively, such devices may be designed to have a wide spectral transmission profile (e.g. a full width half maximum (FWHM) of the spectral transmission profile of approximately 60-120 nm, which is suitable for image grabbing/imaging applications) and to also have a relatively large free spectral range (FSR) between successive peaks on the order of, or larger than 30 nm, thereby providing good color separation.

Devices disclosed herein use for example electrostatic actuation to tune the spectral transmission and other properties of the etalon. The term “electrostatic” actuation is used to refer to close gap actuation provided by a parallel plate electrostatic force between one or more electrodes on each of two layers of a device. For example, in device 100, the electrostatic actuation is performed by applying voltage between one or more regions of frame 108 and one or more electrodes 120 formed/deposited on the bottom surface of cap 118. In device 500, the electrostatic actuation is performed by applying voltage between one or more regions of frame 108 and one or more regions of handle layer 502. This provides tunability of the displacement between the mirrors and therefore of the etalon.

One of the central challenges of the electrostatic actuation is the presence of so-called pull-in instability, which limits the stable displacement of the approaching electrode (e.g. mounting frame 108 in both device 100 and device 500) towards the static electrode (e.g. electrodes 120 or 520) to one-third of the initial gap between them. Thus, in electrostatic actuation configurations disclosed herein, the initial gap between the handle layer and the mounting frame or between the electrodes 120 and the mounting frame is significantly larger (at least 4-5 times) than the required maximal optical gap g_{Mx}. Therefore, the gap between the front and back mirrors in the range g_{Mn} to g_{Mx} is in a stable range of the actuator and the pull-in instability is eliminated.

As mentioned above electrostatic actuation is merely one example of an actuation mechanism used for tuning the gap between the front and back mirrors, which is applicable in MEMS etalon devices as disclosed herein and should not be construed as limiting. The presently disclosed subject matter further contemplates other types of actuation mechanisms such as piezo-electric actuation and Kelvin force actuation.

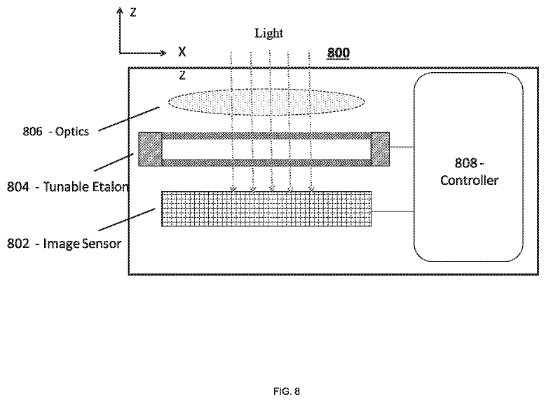

Specifically, in some examples the etalon system includes a piezoelectric actuation structure that is attached to the frame or flexure structures such that application of electric voltage enables actuation of the frame structure (and thereby causes movement of the front mirror) away from the back mirror. In some examples, upon actuation, frame 108 pulls front mirror 104 away from back mirror 102, thereby increasing the size of gap between them and thus increasing the size of the back gap. By placing several piezoelectric actuation structures on different parts/flexures/springs of the frame, the parallelism between the aperture mirror and the back mirror of the etalon can be controlled. Application WO 2017/009850 to the Applicant, which is incorporated herein by reference in its in entirety, describes examples of implantations of piezoelectric and Kelvin force actuation, see for example in FIGS. 8a to 8c and FIGS. 9a and 9b.

Reference is now made to FIG. 8 which illustrates schematically, in a block diagram, a sequential imaging system 800 configured according to an embodiment disclosed herein. System 800 includes an image sensor 802 (for example a multi-pixel sensor) and a tunable MEMS etalon device 804 configured according to the present invention as described above.

Tunable MEMS etalon device 804 serves as tunable spectral filter and is placed in the general optical path of light propagation towards sensor 802 (e.g. intersecting the Z axis in the figure). Optionally, optics 806 (e.g. imaging lens(es)) are also arranged in the optical path of the sensor 802. Color image acquisition can be carried out by the device 800 in similar way as described for example in patent application publication WO 2014/207742, which is assigned to the assignee of the present application and which is incorporated herein by reference. Tunable MEMS etalon device 804 when used in imaging system 800 is configured to provide a spectral filtering profile suitable for sequential color imaging with high color fidelity.

More specifically, according to various examples disclosed herein the materials of the back mirror 102 and front mirror 108 of the etalon and the tunable back gap size are configured such that the spectral filtration profile of the etalon is tunable in the spectral ranges in the visible and possibly also in the IR/near-IR ranges which are suitable for imaging of color images (for example with colors corresponding to the RGB space or to a hyper spectral color space). Also, the front and back mirrors and the tunable back gap size may be configured such that the transmission profile properties (including for example, FWHM and FSM) of the etalon are also suitable for sequential color imaging. For instance, the materials of the front and back mirrors and the tunable back gap size may be selected such that the FWHM of the spectral transmission profile of the etalon is sufficiently wide to match the FWHM of the colors in the conventional RGB space, and also that the FSR between successive transmission peaks in the spectral transmission profile is sufficiently large to avoid color mixing (to avoid simultaneous transmission to the sensor of different colors/spectral-regimes to which the sensor is sensitive). Further, the etalon may be relatively laterally wide (relative to the back gap size), such that it is wide enough to interpose in the optical path between optics 806 and all the pixels of the sensor 802, and on the other hand the gap between its mirrors is small enough to provide the desired spectral transmission properties and the tunability of the etalon.

System 800 may also include a control circuitry (controller) 808 operatively connected to the image sensor 802 and to the tunable MEMS etalon device 804 and configured and operable to tune the filter and to capture image data. For example, the capture of colored image data may include sequential acquisition of monochromatic frames corresponding to different colors (different spectral profiles) from the sensor. For example, controller 808 may be adapted for creating/capturing colored image data by sequentially operating tunable MEMS etalon device 804 for sequentially filtering light incident thereon with three or more different spectral filtering curves/profiles, and operating sensor 802 for acquiring three or more images (monochromatic images/frames) of the light filtered by the three or more spectral curves respectively. Tunable spectral filter (etalon device) 804 is operated to maintain each of the spectral filtering curves for corresponding time slot durations, during which sensor 802 is operated for capturing the respective monochrome images with respective integration times fitting in these time slots. Accordingly, each of the captured monochrome images corresponds to light filtered by a different respective spectral filtering curve and captured by sensor 802 over a predetermined integration time. The control circuitry (e.g. controller) can be further configured to receive and process readout data indicative of the three or more monochrome images from the sensor and generate data indicative of a colored image (namely an image including information on the intensities of at least three colors in each pixel of the image).

In another example, the optical device disclosed herein may be used as a pre-configured filter for specific applications. For example, the device may be pre-configured to assume two different states (and respective operation modes), where the gap between the mirrors in each one of the two states is according to the desired wavelength. For example, one state provides a filter that allows a first wavelength range to pass through the etalon, while the other state allows a second wavelength range to pass through the etalon. Operation of the controller may include switching between a first mode for capturing images in the IR spectrum and a second mode for capturing images in the visible light spectrum.

The terms “controller” as used herein might be expansively construed to include any kind of electronic device with data processing circuitry, which includes a computer processor (including for example one or more of: central processing unit (CPU), a microprocessor, an electronic circuit, an integrated circuit (IC), firmware written for or ported to a specific processor such as digital signal processor (DSP), a microcontroller, a field programmable gate array (FPGA), an application specific integrated circuit (ASIC), etc.) adapted for executing instruction, stored for example on a computer memory operatively connected to the controller, as disclosed herein below.

Any of the mentioned optical devices may be manufactured in various manners. Non-limiting examples of one or more manufacturing processes are illustrated in PCT patent application PCT/IB2017/57261 which is incorporated herein by reference.

FIG. 9 illustrates four example of back mirror 102 and various deformation reduction elements.

Going from top to bottom of FIG. 9:
a. Back mirror 102 includes a deformation reduction element 90′ that is adjacent to the external surface of the back mirror. The deformation reduction element 90′ covers only a part of the back mirror 102. Back mirror 102 may include other layers or components—collectively denoted 103. These layers or components may include at least partially transparent elements, reflecting elements, anti-reflective elements, and the like.
b. Back mirror 102 includes a deformation reduction element 90′ that is adjacent to the internal surface of the back mirror. The deformation reduction element 90′ covers only a part of the back mirror 102. Back mirror 102 may include other layers or components—collectively denoted 103.
c. Back mirror 102 includes a deformation reduction layer 90 and an anti-reflective coating (ARC) layer 91 (or any other coating—especially any other multi-layer coating)—both layers are adjacent to the external surface of the back mirror. The deformation reduction layer 90 is closer to the internal surface of the back mirror than the ARC layer 91. Back mirror 102 may include other layers or components—collectively denoted 103.
d. Back mirror 102 includes a deformation reduction layer 90 and a anti reflective coating (ARC) layer 91—both layers are adjacent to the external surface of the back mirror. The deformation reduction layer 90 is closer to the external surface of the back mirror than the ARC layer 91. Back mirror 102 may include other layers or components—collectively denoted 103.

FIGS. 10A-10C show schematically in cross-sectional views a third example of a tunable MEMS etalon device disclosed herein and numbered 200.

FIG. 10A shows device 200 in an as-fabricated (non-stressed) configuration, before the bonding of anchor structure 112 to the back mirror 102. FIG. 10B shows device 200 in an initial pre-stressed un-actuated state, while FIG. 10C shows device 200 in an actuated state. Device 200 has a similar structure to that of device 100 and includes many of its elements (which are therefore numbered the same).

In some examples, front mirror 104 is formed in a hybrid layer in which the front mirror is made of a transparent or semi-transparent material (to light wavelengths in a desired range transmitted by the tunable etalon filter), and the anchor 112, flexure 114, and frame 108 structures are made of a relatively stiffer material. As shown in FIGS. 10A-10C front mirror is fabricated in alignment (e.g. from a single wafer) with frame 108 rather than being attached thereto from one side. In some examples, front mirror is made of anyone of the following materials: glass; plastic; or germanium, while the anchor 112, flexure 114, and frame 108 structures are made of silicon. It is noted that this list of material is not exhaustive and should not be construed as limiting.

In FIG. 10A, front mirror 104 is not in physical contact with the back stoppers 106 on back mirror 102, while in FIG. 10B, the pre-stress brings front mirror 104 and back stoppers 106 into physical contact. In FIG. 10C, front mirror 104 has moved away from back mirror 102, due to actuation, and is in an intermediate position between the back stoppers 106 and electrodes 120.

In the as-fabricated state, front mirror 104 does not touch back stoppers 106. FIG. 10B shows the device of FIG. 10A in an initial pre-stressed un-actuated state, with front mirror 104 physically touching back stoppers 106. The physical contact is induced by stress applied on the frame through the springs when anchor structure 112 is forced into contact with the glass wafer substrate (which includes back mirror 102) for eutectic bonding to the glass plate of back mirror 102, see FIG. 9(c) below. Notably, height difference between back stoppers 106 and anchors assists in attaining the required stress. Thus, the configuration shown in FIG. 10B is said to be “pre-stressed”.

FIG. 10C shows the device in an actuated state, with front mirror 104 in an intermediate position between back stoppers 106 and front stoppers 122, moved away from back mirror 102. In some examples, actuation is achieved by applying a voltage V between the one or more regions/electrodes 120 of the actuation substrate serving as an actuating electrode and the one or more regions frame 108.

As mentioned above, in some examples, the combined value of the maximal required travel distance (maximal back gap size) g_{Mx} is smaller than one third of an as-fabricated (“electrostatic”) gap size d₀ of a gap between electrodes 120 and frame 108 (FIG. 10A), to provide stable controllable electrostatic operation of the frame by the electrodes located on the cap. In certain examples, the as-fabricated electrostatic gap d₀ may have a value of about 2-4 μm. The requirement for stable operation is g_{Mx}<d₀/3, since the stable travel distance of a capacitive actuator is ⅓ of the as-fabricated electrostatic gap, i.e. is d₀/3.

Note that in certain examples, an un-actuated state may include a configuration in which movable mirror 104 is suspended and does not touch either back stoppers 106 or front stoppers 122.

According to some examples, device 200 is fully transparent. It includes a transparent back mirror (102), a transparent front mirror (104) and a transparent cap (118) as well as transparent anchor 112, flexure 114, and frame 108 structures. One advantage of the full transparency is that the device can be observed optically from two sides. Another advantage is that this architecture may be useful for many other optical devices incorporating movable mechanical/optical elements, such as minors, diffractive gratings or lenses.

FIGS. 11-15 illustrates various portions 201 an optical device.

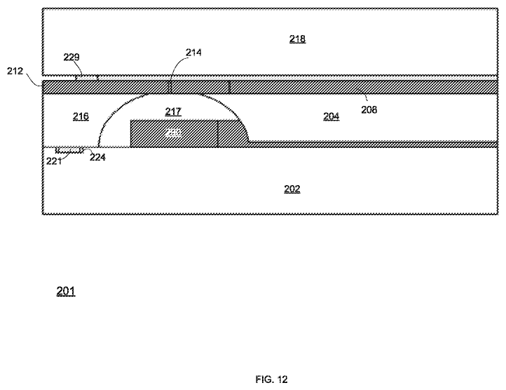

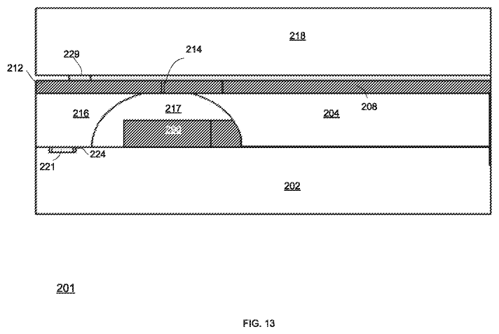

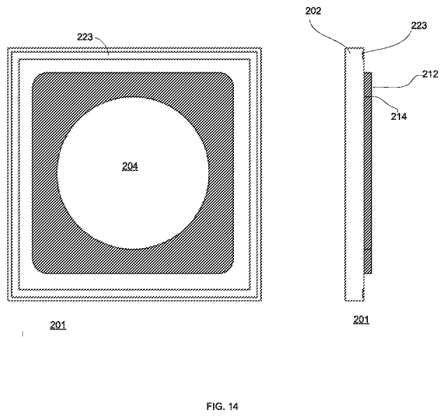

FIG. 11 is an exploded perspective illustration of portion 201, FIGS. 12 and 13 are cross sectional views of portion 201, and FIG. 14 includes a top view and a side cross-section view of portion 201.

FIG. 11-13 illustrate, from top to bottom, the following elements:
a. A first element—such as first planar object (also referred to as cap) 218. A first eutectic bond frame 229 or any other arrangement of a eutectic bonding material may be positioned between the bottom surface of the first element and an upper surface of an anchor. At least a first region 215 of the first element 218 (cap) may be at least partially transparent. In FIG. 11 the entire first element 218 is at least partially transparent.
b. A movable element that may include third region 204 and frame 208. Third region 204 is mechanically coupled to frame 208. Frame 208 may be mechanically coupled vias spring 214 to anchor 212. An actuation of the movable element may move frame 208 in relation to anchor 212. The third region 204 follows the movement of frame 208. In FIG. 11 the frame 208, the spring 214 and the anchor 212 are formed in a silicon layer and are positioned above a glass layer that includes the first region 204 and spacer 216. A cavity 217 is formed, in the glass layer, between first region 204 and spacer 216.
c. A second element—such as back mirror 202—that may include second region 205. Second region 205 may be at least partially transparent and may include at least partially a back mirror coating. In FIG. 11 the entire second element 218 is at least partially transparent. A recess 223 is formed in the back mirror and is configured to receive a eutectic bonding material. The recess may be wider than the eutectic bonding material—before the first element, movable element and the second element are pressed towards each other. A deformation reduction element—such as deformation reduction frame 290 is located on top of the back mirror 202. The deformation reduction frame 290 surrounds second region 205 and may be located (at least in part) within cavity 217.

The eutectic bonding material is used to bond back mirror 202 to spacer 216 and may form a frame. The eutectic bonding material can be arranged in other manners. FIG. 11 illustrates the first and second recesses as located at the periphery of the back mirror 202—but they may be located elsewhere.

In FIG. 12 the third region 204 is spaced apart from back mirror 202. In FIG. 13 the third region 204 contacts the back mirror 202.

FIGS. 12 and 13 illustrate recess 223 as being wider than the eutectic bonding material 221 to form gaps 224 at both sides of the eutectic bonding material 221.

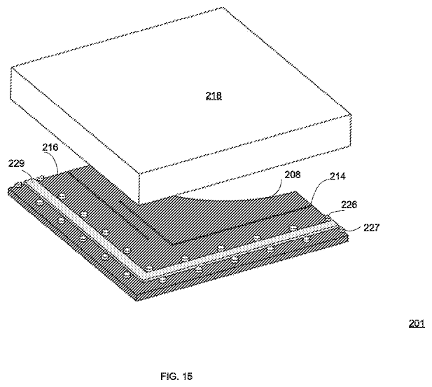

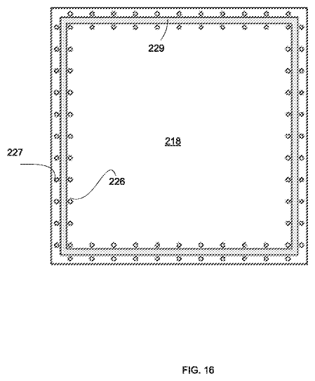

FIGS. 15 and 16 illustrate that the first eutectic bond frame 229 may be positioned between a set of internal spacers 226 and a set of external spacers 227. The internal spacers are surrounded by the first eutectic bond frame 229. The external spacer surround the first eutectic bond frame 229. In FIGS. 15-16 each of the internal spacer faces an external spacer.

It should be noted that the internal spacers may be of the same shape and size as the external spacers, all internal spacers may be of the same shape, all internal spacers may be the same size, some internal spacers may differ by shape from each other, some internal spacers may differ by size from each other, all external spacers may be of the same shape, all external spacers may be the same size, some external spacers may differ by shape from each other, some external spacers may differ by size from each other, at least one internal spacer may differ from at least one external spacer, at least one internal spacer may be the same as at least one external spacer, and the like.

The number of internal spacers may be the same as the number of external spacers. The number of internal spacers may differ from the number of external spacers.

The internal spacers and/or the external spacers may be arranged in the same manner or may be arranged in different manners.

The spacers shown in FIGS. 15-16 are in the periphery of the cap 218—but may be positioned elsewhere.

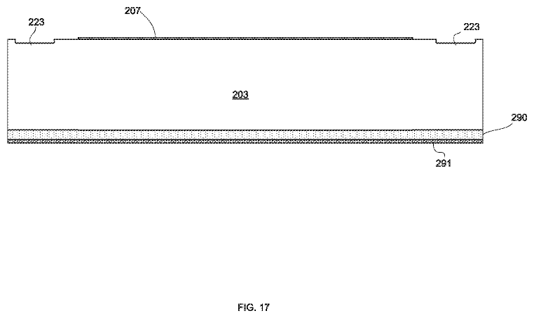

FIG. 17 illustrates back mirror 202. A recess 223 is formed in the back mirror 202 and is configured to receive second eutectic bond frame (not shown).

Back mirror 202 includes a deformation reduction layer 290 and ARC layer 291 that is located closer to the exterior of back mirror than deformation reduction layer 290. Back mirror 202 may include other layers or components—collectively denoted 207. These layers or components may include at least partially transparent elements, reflecting elements, anti-reflective elements, and the like.

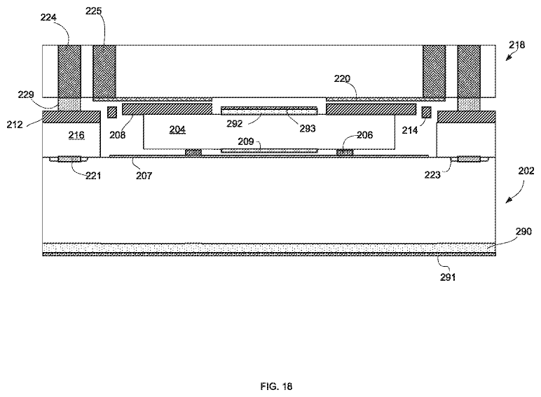

FIG. 18 illustrates a portion of an optical unit, the portion includes cap 218, through vias 224 and 225 that pass through cap 218, cap electrode 220 that is connected to a bottom surface of cap 218, anchor 212, first eutectic bond frame 229 that bonds anchor 212 to electrode 224, frame 208, third region 204, frame 208, spring 214, recess 223, eutectic bonding material 221, first ARC layer 293 and first deformation reduction element 292 that are positioned on the top surface of third region 204, back stopper 206 that enforce a gap between third region 204 and back mirror 202, deformation reduction layer 290, and optical coatings 207 and 209.

FIG. 19 illustrates a portion of an optical unit that differs from the optical unit of FIG. 18 by not including first ARC layer 293 and first deformation reduction element 292.

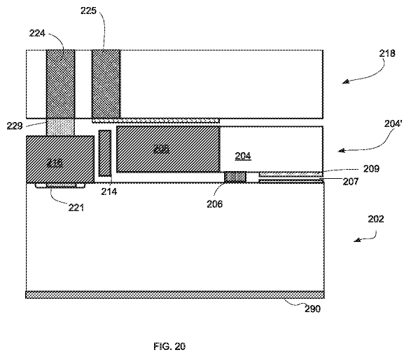

FIG. 20 illustrates a portion of an optical unit that differs from the optical unit of FIG. 19 by having the frame 208 and the third region 204 of the movable element 204′ at the same plane—as a part of a hybrid element that may include at least partially transparent regions that are surrounded by non-transparent areas.

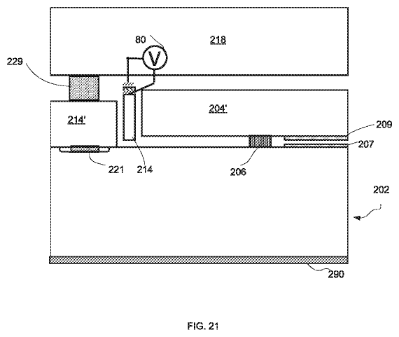

FIG. 21 illustrates a portion of an optical unit, the portion includes cap 218, a piezoelectric actuated spring 80, bulk 216′ that acts as an anchor and a spacer, first eutectic bond frame 229 that bonds bulk 214′ to cap 218, a movable element 204′ that does not include a frame, a recess with eutectic bonding material 221, back stopper 206, back mirror 202, deformation reduction layer 290, and optical coatings 207 and 209. Cap 218, movable element 204′ and back mirror are made of an at least partially transparent material.

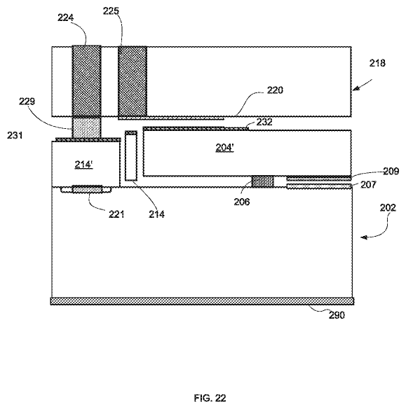

FIG. 22 illustrates a portion of an optical unit, the portion includes cap 218, spring 214, bulk 214′ that acts as an anchor and a spacer, electrodes 224 and 225 that pass through cap 218, first eutectic bond frame 229 that bonds bulk 214′ to cap 218, a movable element 204′ that does not include a frame, a recess with eutectic bonding material 221, back stopper 206, back mirror 202, deformation reduction layer 290, electrodes 231 and 232 that are coupled via the electrode deposited on spring 214 and optical coatings 207 and 209. Movable element 204′ and back mirror are made of an at least partially transparent material.

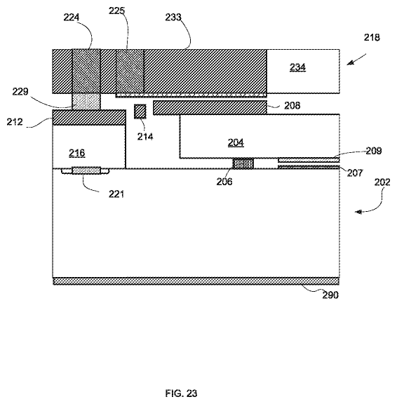

FIG. 23 illustrates a portion of an optical unit, the portion includes cap 218, spring 214, anchor 212, spacer 216, electrodes 224 and 225 that pass through cap 218, first eutectic bond frame 229 that bonds anchor 212 to cap 218, third region 204, frame 208, a recess with eutectic bonding material 221, back stopper 206, back mirror 202, deformation reduction layer 290, and optical coatings 207 and 209. Cap 218 include first region 234 that is at least partially transparent and include non-transparent parts 223 (that such as silicon parts) through which electrodes 224 and 225 pass. The non-transparent part 223 may act as a deformation reduction element.

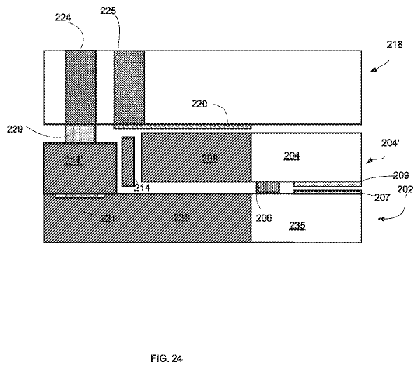

FIG. 24 illustrates a portion of an optical unit, the portion includes cap 218, spring 214, bulk 214′ that acts as an anchor and a spacer, electrodes 224 and 225 that pass through cap 218, first eutectic bond frame 229 that bonds bulk 214′ to cap 218, a movable element 204′, a recess with eutectic bonding material 221, electrodes 231 and 232 , back stopper 206, back mirror 202, deformation reduction layer 290, and optical coatings 207 and 209. The frame 208 and the third region 204 of the movable element 204′ at the same plane—as a part of a hybrid element that may include at least partially transparent regions that are surrounded by non-transparent areas. Back mirror 202 includes second region 235 that is at least partially transparent and includes a non-transparent part 236 (that such as a silicon pars). The non-transparent part 236 may act as a deformation reduction element.

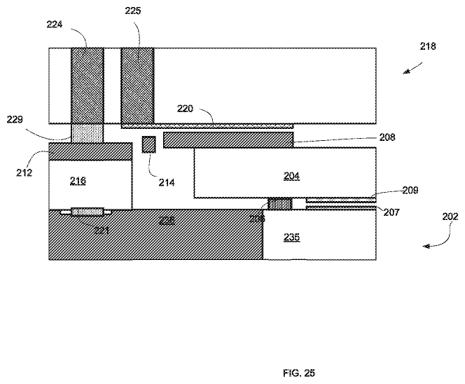

FIG. 25 illustrates a portion of an optical unit, the portion includes cap 218, spring 214, anchor 212, spacer 216, electrodes 224 and 225 that pass through cap 218, first eutectic bond frame 229 that bonds anchor 12 to cap 218, electrode 220, third region 204, frame 208, a recess with eutectic bonding material 221, back stopper 206, back mirror 202, and optical coatings 207 and 209. Back mirror 202 includes second region 235 that is at least partially transparent and includes a non-transparent part 236 (that such as a silicon pars). The non-transparent part 236 may act as a deformation reduction element.

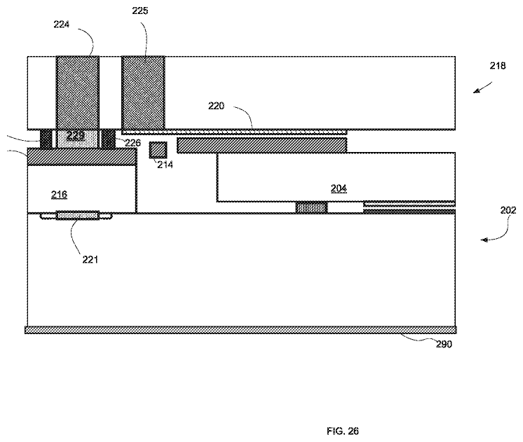

FIG. 27 differs from FIG. 26 by showing internal spacers 226 and external spacers 227 that surround the first eutectic bond frame 229.

It should be noted that any of the optical units may include a deformation reduction element that differs from deformation reduction layer 290—and may be included in addition to deformation reduction layer 290 or instead of deformation reduction layer 290.

### EMBODIMENTS

Some non-limiting embodiments of this disclosure are listed below in the following numbered paragraph. These are intended to add onto and not derogate from the other sections of this disclosure.
1. An optical device comprising:
   an enclosure having a first surface and a second surface, each configured to allow transmission of light through at least a portion thereof (e.g. transmission of visible light and infra-red spectra), and wherein the first and second surfaces defines a vacuumed space therebetween (namely, below ambient pressure);
   a movable member configured to (controllably) move within the vacuumed space, wherein the position of the movable member defines an optical gap between the movable member and at least one of the first and second surfaces;
   wherein said optical gap defines the transmission spectrum through the optical device (namely, filtering desired wavelengths according to a certain transmission function).
2. The optical device of embodiment 1, wherein the movable member is configured to allow transmission of light through at least a portion thereof
3. The optical device of embodiment 1 or 2, wherein optical regions of the first and second surfaces and the movable member define an optical path (the optical path passes through the active optical portions of the optical elements of the device).
4. The optical device of embodiment 3, wherein the optical region of at least one of the first and second surfaces is characterized with a deformation (e.g. a bow) lower than 5, 10, 15 or 20 nm.
5. The optical device of embodiment 3, wherein the optical region of at least one of the first and second surfaces is characterized by a maximal distance (e.g. a vertical distance along the optical axis) between two portions of the optical region lower than 5, 10, 15 or 20 nm.
6. The optical device of any one of embodiments 1-5, wherein the movable member is configured to move at least along an optical axis of the device.
7. The optical device of any one of embodiments 1-6, wherein the movement of the movable member is limited to a minimal optical gap.
8. The optical device of embodiment 7, wherein the minimal optical gap is lower than one of 2000 nm, 1000 nm, 500 nm, 400 nm, 300 nm, 200 nm or 100 nm.
9. The optical device of embodiment 7, wherein the minimal optical gap is between about 2 nm and about 200 nm, about 3 nm and about 150 nm or about 10 nm and about 100 nm.
10. The optical device of any one of embodiments 7-9, wherein the aspect ratio between the minimal optical gap and the largest dimension of the movable member (e.g. diameter, width, etc.) may be at least 1:10 and up to 1:100, 1:1000, 1:10000, 1:100000, 1:1000000 or even up to 1:10000000.
11. The optical device of any one of embodiments 1-10, wherein the movable member is parallel to at least one of the first and second surfaces.
12. The optical device of any one of embodiments 1-11, wherein at least one of the first and second surfaces has a thickness of above 200 microns or a thickness of above 300 microns.
13. The optical device of any one of embodiments 1-12, comprising a deformation reduction element that is formed on at least one of the first and second surfaces.
14. The optical device of embodiment 13, wherein the deformation reduction element is formed on one or both of internal or external surfaces of said at least one of the first and second surfaces(The deformation reduction element provides a mechanical support to the surface and/or a counter force opposing the force that is applied on the enclosure due to the pressure differences).
15. The optical device of embodiment 13 or 14, wherein the deformation reduction element is formed of one or more optical layers.
16. The optical device of embodiment 15, wherein said one or more optical layers comprise at least one of anti-reflecting layers and transparent layers (e.g. layers comprising oxide such as Silicon Oxide).
17. The optical device of embodiment 13 or 14, wherein the deformation reduction element is formed of silicon.
18. The optical device of any one of embodiments 1-17, wherein the first and second surfaces and the movable member comprise glass.
19. The optical device of any one of embodiment 1-18, wherein at least one of the first and second surfaces is formed of one or more layers of composite structure that comprises a first material that is configured to allow transmission of light therethrough and
   a second material that is stiffer than the first material (e.g. wafer of composite structure of silicon and glass).
20. The optical device of embodiment 19, wherein the first material is glass and the second material is silicon.
21. The optical device of any one of embodiments 1-20, wherein the movable member is configured to move by an electrostatic force (e.g. upon electrostatic actuation).
22. The optical device of embodiment 21, wherein the electrostatic force is applied between the movable member and at least one of the first and second surfaces.
23. The optical device of any one of embodiments 1-22, being a tunable filter.
24. The optical device of embodiment 23, wherein the tunable filter is an etalon.
25. An imaging system comprising the optical device of any one of embodiments 1-24.
26. The imaging system of embodiment 25, comprising an image sensor configured to receive light passing through the first and second surfaces and the movable member.
27. An optical device comprising:
   at least a first element and a second element bonded to one another by a bond, wherein at least one of the first and second elements is formed with a solder recess that comprises solder such that the top portion of the solder contacts the other element to form the eutectic bond;
   an excess solder space having at least one common surface (e.g. wall) with the solder recess and is configured to receive excess solder upon eutectic bonding the first and second element.
28. The optical device of embodiment 27, wherein the bond is a eutectic bond.
29. The optical device of embodiment 28, wherein the excess solder space laterally surrounds the solder recess.
30. The optical device of any one of embodiments 27-29, wherein one of the first and second elements constitutes frame links to a movable member that is configured to move at least along an optical axis of the optical device, wherein the position of the movable member defines an optical gap with the other element not constituting the frame, said optical gap defines transmission spectrum of the optical device.
31. The optical device of embodiment 30, wherein the frame and the movable member are formed in a single wafer.
32. The optical device of any one of embodiments 27-31, wherein the element formed with the solder recess spans a plane and top portions of walls of the solder recess lies on said plane.
33. The optical device of any one of embodiments 27-32, being a tunable filter.
34. The optical device of embodiment 33, wherein the tunable filter is an etalon.

The optical devices and/or the tunable filters disclosed in the application are compact and may easily fit in small spaces—which is highly beneficial in compact devices such as but not limited mobile phones and especially smartphones. All patents and patent applications mentioned in this application are hereby incorporated by reference in their entirety for all purposes set forth herein. It is emphasized that citation or identification of any reference in this application shall not be construed as an admission that such a reference is available or admitted as prior art.

While this disclosure has been described in terms of certain embodiments and generally associated methods, alterations and permutations of the embodiments and methods will be apparent to those skilled in the art. The disclosure is to be understood as not limited by the specific embodiments described herein, but only by the scope of the appended claims.

to The various features and steps discussed above, as well as other known equivalents for each such feature or step, can be mixed and matched by one of ordinary skill in this art to perform methods in accordance with principles described herein. Although the disclosure has been provided in the context of certain embodiments and examples, it will be understood by those skilled in the art that the disclosure extends beyond the specifically described embodiments to other alternative embodiments and/or uses and obvious modifications and equivalents thereof Accordingly, the disclosure is not intended to be limited by the specific disclosures of embodiments herein.

Unless otherwise stated, the use of the expression “and/or” between the last two members of a list of options for selection indicates that a selection of one or more of the listed options is appropriate and may be made.

It should be understood that where the claims or specification refer to “a” or “an” element, such reference is not to be construed as there being only one of that element.

It is appreciated that certain features of the invention, which are, for clarity, described in the context of separate embodiments or example, may also be provided in combination in a single embodiment. Conversely, various features of the invention, which are, for brevity, described in the context of a single embodiment, may also be provided separately or in any suitable sub-combination or as suitable in any other described embodiment of the invention. Certain features described in the context of various embodiments are not to be considered essential features of those embodiments, unless the embodiment is inoperative without those elements.

All patents and patent applications mentioned in this application are hereby incorporated by reference in their entirety for all purposes set forth herein. It is emphasized that citation or identification of any reference in this application shall not be construed as an admission that such a reference is available or admitted as prior art.

The terms “including”, “comprising”, “having”, “consisting” and “consisting essentially of” are used in an interchangeable manner. For example- any method may include at least the steps included in the figures and/or in the specification, only the steps included in the figures and/or the specification.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front, ” “back, ” “top, ” “bottom, ” “over, ” “under ” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one as or more than one. Also, the use of introductory phrases such as “at least one ” and “one or more ” in the claims should not be construed to imply that the introduction of another claim element by the indefinite articles “a ” or “an ” limits any particular claim containing such introduced claim element to inventions containing only one such element, even when the same claim includes the introductory phrases “one or more ” or “at least one ” and indefinite articles such as “a ” or “an. ” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements the mere fact that certain measures are recited in mutually different claims does not indicate that a combination of these measures cannot be used to advantage.

Any system, apparatus or device referred to this patent application includes at least one hardware component.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

Any combination of any component of any component and/or unit that is illustrated in any of the figures and/or specification and/or the claims may be provided.

Any combination of any optical device illustrated in any of the figures and/or specification and/or the claims may be provided.

Any combination of steps, operations and/or methods illustrated in any of the figures and/or specification and/or the claims may be provided.

Any combination of operations illustrated in any of the figures and/or specification and/or the claims may be provided.

Any combination of methods illustrated in any of the figures and/or specification and/or the claims may be provided.

While this disclosure has been described in terms of certain embodiments and generally associated methods, alterations and permutations of the embodiments and methods will be apparent to those skilled in the art. The disclosure is to be understood as not limited by the specific embodiments described herein, but only by the scope of the appended claims.

1. An optical device, comprising:
an enclosure that comprises a first element and, a second element; wherein the first element and the second element are at least partially transparent;
a movable element that is configured to move within an internal space defined by the enclosure; and
wherein the enclosure is sealed and is configured to maintain a pressure difference between a pressure level that exists within the internal space and an ambient pressure level.

2. The optical device according to claim 1, wherein the first element comprises a first region that is at least partially transparent; wherein the second element comprises a second region that is at least partially transparent; and wherein at least one optical path exists between the first region, and the second region.

3. The optical device according to claim 1, wherein the first element comprises a first region that is at least partially transparent; wherein the second element comprises a second region that is at least partially transparent; wherein the movable element comprises a third region that is at least partially transparent; and wherein at least one optical axis passes through the first region, the second region, and the third region.

4. The optical device according to claim 1, comprising a deformation reduction element.

5. The optical device according to claim 4 wherein the deformation reduction element is mechanically coupled to the first element.

6. The optical device according to claim 4 wherein the deformation reduction element is coupled to the movable element.

7. The optical device according to claim 4 wherein the movable element comprises the third region and the deformation reduction element.

8. The optical device according to claim 4, wherein the deformation reduction element is mechanically coupled to the second element.

9. The optical device according to claim 1, comprising a recess that comprises a main space for receiving eutectic bonding material, and one or more additional spaces for receiving excess eutectic bonding material.

10. The optical device according to claim 1, comprising a eutectic bond and multiple spacers that are positioned at both sides of the eutectic bond.

11. The optical device according to claim 1, comprising one or more bonds for sealing the enclosure.

12. The optical device according to claim 1, wherein the optical device is a tunable filter.

13. An optical device, comprising:
an enclosure that comprises a first element and a second element;
a movable element that is configured to move within an internal space defined by the enclosure; and
a deformation reduction element;
wherein the enclosure is configured to maintain a pressure difference between a pressure level that exists within the internal space and an ambient pressure level; and
wherein the deformation reduction element is configured to reduce deformations formed in the enclosure due to the pressure difference.

14. The optical device according to claim 13, wherein at least one of the first element and second element is at least partially transparent.

15. The optical device according to claim 13, wherein the first element comprises a first region that is at least partially transparent; wherein the second element comprises a second region that is at least partially transparent; wherein the movable element comprises a third region that is at least partially transparent; and wherein at least one optical axis passes through the first region, the second region, and the third region.

16. (canceled)

17. The optical device according to claim 13, wherein the deformation reduction element is mechanically coupled to the second element and is more rigid than the second element.

18. The optical device according to claim 13, wherein a recess is formed in the first element and wherein the recess defines a main space for receiving eutectic bonding material and one or more additional spaces for receiving excess eutectic bonding material.

19. The optical device according to claim 13, wherein at least one of the first and second elements comprises a region that is at least partially transparent; and wherein the movable element comprises another region that is at least partially transparent; and wherein at least one optical axis passes through all regions that are partially transparent.

20. The optical device according to claim 13, wherein the optical device is a tunable filter.

21. A tunable filter, comprising:
an enclosure that comprises a first element and a second element, wherein the second element comprises a back mirror;
a movable element that comprises a top mirror and is configured to move within an internal space defined by the enclosure; and
a deformation reduction element;
wherein a spatial relationship between the top mirror and the back mirror defines a spectral response of the tunable filter;
wherein the enclosure is configured to maintain a pressure difference between a pressure level that exists within the internal space and an ambient pressure level; and
wherein the deformation reduction element is configured to reduce deformations formed in the enclosure due to the pressure difference.

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)
